(19) United States
(12) Patent Application Publication
(10) Pub. No.: US 2026/0215097 A1
(43) Pub. Date: Jul. 23, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Su Yeon SIM, Yongin-si (KR); Jeong Woo PARK, Yongin-si (KR); Beom Shik KIM, Yongin-si (KR)

(21) Appl. No.: 19/434,505

(22) Filed: Dec. 29, 2025

(30) Foreign Application Priority Data
Jan. 20, 2025 (KR) 10-2025-0008117

(51) Int. Cl. H10K 59/122; G02F 1/01; G02F 1/139; H10K 59/50; H10K 59/80

(52) U.S. Cl. CPC H10K 59/122; G02F 1/0136; G02F 1/1396; H10K 59/50; H10K 59/879; H10K 59/8792

(57) ABSTRACT

A display device and an electronic device including the same are provided. The display device includes a display panel, and an optical member on the display panel. The optical member includes a plurality of lenses that refracts light output from the display panel, and a plurality of first light-blocking members arranged between the plurality of lenses. The display panel may include a substrate, a plurality of pixel electrodes arranged on the substrate, a pixel-defining layer exposing a portion of each of the plurality of pixel electrodes and defining a plurality of light-emitting areas, a plurality of light-emitting layers arranged on the plurality of pixel electrodes in the plurality of light-emitting areas, a common electrode arranged on the plurality of light-emitting layers and the pixel-defining layer, and a plurality of second light-blocking members arranged on the pixel-defining layer and each arranged on at least one side of each of the plurality of light-emitting areas.

This application claims priority under 35 U.S.C. § 119 to Korean Patent Application No. 10-2025-0008117, filed on Jan. 20, 2025 in the Korean Intellectual Property Office, the present disclosure of which is incorporated by reference in its entirety herein.

### 1. TECHNICAL FIELD

The present disclosure relates to a display device and an electronic device including the same.

### 2. DISCUSSION OF RELATED ART

Display devices are being used to display images to users in an increasing variety of places and environments along with the advancement of communication technology and media. In particular, a variety of types of display devices such as liquid-crystal display (LCD) devices and organic light-emitting diode (OLED) devices are widely used.

Recently, a three-dimensional (3D) image display device has been developed, which provides divided images of the display device in the space in front of the display device using a lens array. A 3D image display device utilizes the stereoscopic technique that separately displays a left-eye image and a right-eye image to provide a viewer 3D experiences using binocular parallax.

The stereoscopic technique may include a glass-free 3D display technique that implements 3D images by displaying multiple view images in their respective view areas using an optical plate so that the user can enjoy 3D experiences depending on the point of view. Unfortunately, in the view areas of the glasses-free 3D display technique, 3D crosstalk may occur which results in view images on other view areas being perceived by users which decreases the quality of the 3D images.

### SUMMARY

Aspects of the present disclosure provide a display device that can prevent or reduce 3D crosstalk.

Aspects of the present disclosure provide an electronic device including a display device that can prevent or reduce 3D crosstalk.

According to an embodiment of the present disclosure, a display device includes a display panel. An optical member is disposed on the display panel and comprises a plurality of lenses that refracts light output from the display panel, and a plurality of first light-blocking members arranged between the plurality of lenses. The display panel comprises a substrate. A plurality of pixel electrodes is arranged on the substrate. A pixel-defining layer exposes a portion of each of the plurality of pixel electrodes and defines a plurality of light-emitting areas. A plurality of light-emitting layers is arranged on the plurality of pixel electrodes in the plurality of light-emitting areas. A common electrode is arranged on the plurality of light-emitting layers and the pixel-defining layer. A plurality of second light-blocking members is arranged on the pixel-defining layer and each is arranged on at least one side of the plurality of light-emitting areas. A minimum distance between first light-blocking members adjacent to each other in a first direction parallel to an upper surface of the substrate among the plurality of first light-blocking members is a first distance. A minimum distance between second light-blocking members adjacent to each other in the first direction among the plurality of second light-blocking members is a second distance that is less than the first distance.

According to an embodiment, each of the plurality of second light-blocking members may surround light-emitting area of the plurality of light-emitting areas on a plane.

According to an embodiment, the plurality of light-emitting areas may be arranged adjacent to each other in the first direction and a second direction perpendicular to the first direction on a plane. The plurality of lenses may extend in a third direction crossing the first direction and the second direction on the plane.

According to an embodiment, the plurality of first light-blocking members may extend in the third direction on the plane.

According to an embodiment, a height of the plurality of second light-blocking members may be less than a height of the pixel-defining layer in a thickness direction of the substrate.

According to an embodiment, the plurality of second light-blocking members may be arranged between the pixel-defining layer and the common electrode.

According to an embodiment, the display device may further include an encapsulation layer disposed on the common electrode. The plurality of second light-blocking members may be arranged between the common electrode and the encapsulation layer.

According to an embodiment, each of the plurality of light-emitting areas may include first to fourth sides. The first side may be adjacent to one of the plurality of second light-blocking members. The second side may be opposite to the first side on a plane. The third side may connect a first end of the first side with a first end of the second side. The fourth side may connect an opposite second end of the first side with an opposite second end of the second side. The plurality of second light-blocking members may be solely arranged on the first side and the second side of the plurality of light-emitting areas.

According to an embodiment, the plurality of light-emitting areas may include a first group of light-emitting areas that emit light in a first period, and a second group of light-emitting areas that emit light in a second period different from the first period.

According to an embodiment, the plurality of second light-blocking members may be solely arranged on at least one side of the first group of the light-emitting areas.

According to an embodiment, the optical member may further include a polarizer.

According to an embodiment, the optical member may further include a first base substrate disposed on a first side of the plurality of lenses and a second base substrate disposed on an opposite second side of the plurality of lenses, and a liquid-crystal layer arranged on the plurality of lenses and the plurality of first light-blocking members and in direct contact with a lower surface of the first base substrate.

According to an embodiment, the optical member may further include a first base substrate disposed on a first side of the plurality of lenses and a second base substrate disposed on an opposite second side of the plurality of lenses, and a polarization controller disposed on a lower surface of the second base substrate that outputs light incident from the display panel as one of a first polarized light and a second polarized light.

According to an embodiment, the polarization controller may include a third base substrate in direct contact with the lower surface of the second base substrate, a fourth base substrate facing the third base substrate, a first driving electrode disposed on a surface of the third base substrate, a second driving electrode disposed on a surface of the fourth base substrate and facing the first driving electrode, and a driving liquid crystal disposed between the first driving electrode and the second driving electrode.

According to an embodiment, in response to a voltage difference between the first driving electrode and the second driving electrode that is less than or equal to a first value, a major axis of the driving liquid crystal may be aligned in the first direction at a lower portion of the driving liquid crystal, may be changed gradually towards an upper portion of the driving liquid crystal and may be aligned in a second direction perpendicular to the first direction at the upper portion of the driving liquid crystal.

According to an embodiment, in response to the voltage difference between the first driving electrode and the second driving electrode that is greater than the first value, the major axis of the driving liquid crystal may be aligned in a third direction perpendicular to the first direction and the second direction.

According to an embodiment of the present disclosure, an electronic device includes a display device including a display panel and an optical member disposed on the display panel. The optical member is disposed on the display panel and comprises a plurality of lenses that refracts light output from the display panel, and a plurality of first light-blocking members arranged between the plurality of lenses. The display panel comprises a substrate. A plurality of pixel electrodes is arranged on the substrate. A pixel-defining layer exposes a portion of each of the plurality of pixel electrodes and defines a plurality of light-emitting areas. A plurality of light-emitting layers is arranged on the plurality of pixel electrodes in the plurality of light-emitting areas. A common electrode is arranged on the plurality of light-emitting layers and the pixel-defining layer. A plurality of second light-blocking members is arranged on the pixel-defining layer and each is arranged on at least one side of the plurality of light-emitting areas. A minimum distance between first light-blocking members adjacent to each other in a first direction parallel to an upper surface of the substrate among the plurality of first light-blocking members is a first distance. A minimum distance between second light-blocking members adjacent to each other in the first direction among the plurality of second light-blocking members is a second distance that is less than the first distance.

According to an embodiment, each of the plurality of second light-blocking members may surround a light-emitting area of the plurality of light-emitting areas.

According to an embodiment, each of the plurality of light-emitting areas may include first to fourth sides. The first side may be adjacent to one of the plurality of second light-blocking members. The second side may be opposite to the first side on a plane. The third side may connect a first end of the first side with a first end of the second side. The fourth side may connect an opposite second end of the first side with an opposite second end of the second side. The respective of the plurality of second light-blocking members may be arranged solely on the first side and the second side of the respective of the plurality of light-emitting areas.

According to an embodiment, the plurality of light-emitting areas may include a first group of light-emitting areas that emit light in a first period, and a second group of light-emitting areas that emit light in a second period different from the first period.

According to some embodiments, a display device has a plurality of second light-blocking members surrounding the light-emitting areas so that the amount of light traveling to the edges of a plurality of lenses can be reduced. In this manner, it is possible to reduce 3D crosstalk occurring at the edges of the lenses.

In addition, the display device has a plurality of first light-blocking members arranged between a plurality of lenses, so that it is possible to prevent light traveling toward the edges of the lenses from being refracted at the lenses on the opposite sides. In this manner, it is possible to effectively prevent 3D crosstalk.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is an exploded perspective view of a display device according to some embodiments of the present disclosure;

FIG. 2 is a perspective view of a display device according to some embodiments of the present disclosure;

FIG. 3 is a cross-sectional view for illustrating the optical member taken along line I-I′ of FIG. 1 according to some embodiments of the present disclosure;

FIG. 4 is a cross-sectional view for illustrating the optical member taken along line I-I′ of FIG. 1 according to some embodiments of the present disclosure;

FIG. 5 is a cross-sectional view for illustrating the optical member taken along line I-I′ of FIG. 1 according to some embodiments of the present disclosure;

FIG. 6 is a cross-sectional view for illustrating the optical member taken along line I-I′ of FIG. 1 according to some embodiments of the present disclosure;

FIG. 7 is an enlarged view of portion A of FIG. 2 according to some embodiments of the present disclosure;

FIG. 8 is a cross-sectional view of the display device, taken along line J-J′ of FIG. 7 according to some embodiments of the present disclosure;

FIG. 9 is a cross-sectional view of the display device, taken along line J-J′ of FIG. 7 according to some embodiments of the present disclosure;

FIG. 10 is an enlarged view of portion A of FIG. 2 according to some embodiments of the present disclosure;

FIG. 11 is an enlarged view of portion A of FIG. 2 according to some embodiments of the present disclosure;

FIG. 12 is a cross-sectional view of the display device, taken along line K-K′ of FIG. 11 according to some embodiments of the present disclosure;

FIG. 13 is an enlarged view of portion A of FIG. 2 according to some embodiments of the present disclosure;

FIG. 14 is a cross-sectional view of the display device, taken along line L-L′ of FIG. 13 according to some embodiments of the present disclosure;

FIG. 15 is a block diagram showing an example of an electronic device including a display device according to some embodiments of the present disclosure; and

FIG. 16 is a view showing an example of an electronic device including a display device according to some embodiments of the present disclosure

### DETAILED DESCRIPTION OF EMBODIMENTS

Advantages and features of the present disclosure and methods of achieving the same will become apparent with reference to the non-limiting embodiments described below in detail in conjunction with the accompanying drawings. However, the present disclosure is not limited to embodiments to be described below.

When an element or layer is referred to as being “on” another element or layer, it includes both a case in which the element or layer is directly on another element or layer and a case in which the element or layer is on another element or layer with the other element or layer interposed therebetween. When an element or layer is referred to as being “directly on” another element or layer, no intervening elements may be present. The same reference numbers indicate the same components throughout the specification. Shapes, sizes, proportions, angles, numbers, and the like, disclosed in the drawings for describing embodiments are examples, and thus, the present disclosure is not necessarily limited to those illustrated in the drawings.

The individual features of the various embodiments of the present disclosure may be partially or wholly coupled or combined with each other, and may be technically linked and operated in various ways. The respective embodiments may be implemented independently of one another or may be implemented together in a related relationship.

Hereinafter, non-limiting embodiments of the present disclosure will be described in detail with reference to the accompanying drawings.

The present disclosure concerns a display device having a display panel including a plurality of light-emitting areas and an optical member disposed on the display panel. The optical member includes first light-blocking members arranged between a plurality of lenses in a plan view and a plurality of second light-blocking members arranged on at least one side of the plurality of light-emitting areas. The second light-blocking members are formed only at the borders of the light emitting areas.

A minimum distance between adjacent second light-blocking members is less than a minimum distance between adjacent first light-blocking members. Therefore, the area of the second light-blocking members visible to the user can be reduced.

The plurality of second light-blocking members prevents light emitted from the light-emitting areas from being directed to the edges of the plurality of lenses. The plurality of first light-blocking members prevents light traveling towards the edges of the lenses from being refracted at the lenses on the opposite sides. Therefore, 3D crosstalk is reduced or eliminated to increase the display quality of the display panel.

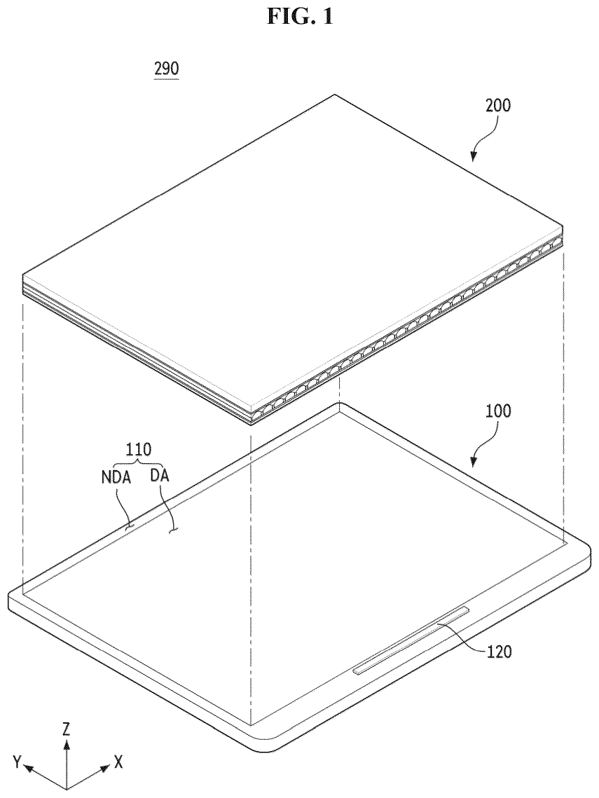

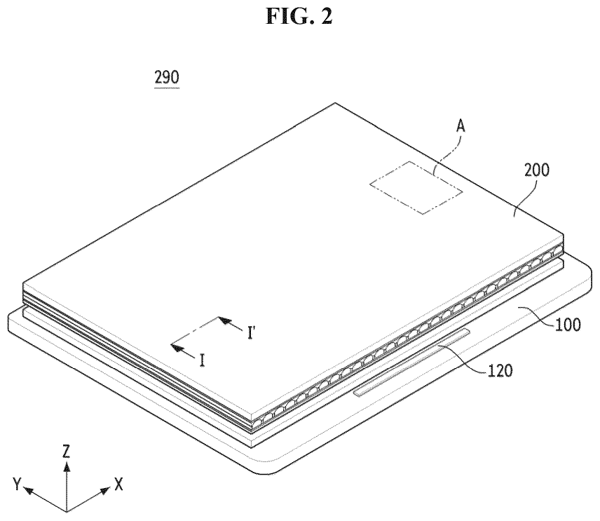

FIG. 1 is an exploded, perspective view of a display device according to some embodiments of the present disclosure. FIG. 2 is a perspective view of a display device according to some embodiments of the present disclosure.

In an embodiment, a display device 290 may be implemented as a flat panel display device such as a liquid-crystal display (LCD) device, a field emission display (FED) device, a plasma display panel (PDP) device, and an organic light-emitting display (OLED) device.

In an embodiment, the display device 290 may be a stereoscopic image display device including a display module 100 and an optical member 200, such as a 3D image display device. To display 3D images, the 3D image display device separately displays a left-eye image and a right-eye image on the front side to give a viewer 3D experiences utilizing binocular parallax. Furthermore, the 3D image display device may separately provide images at different viewing angles from each other on the front side of the display device so that different images are displayed at the different viewing angles.

According to an embodiment of the present disclosure, the display device 290 may be a light-field display device that allows different image information to be seen by a viewers' eyes, respectively, by disposing the optical member 200 on the front side of the display module 100. In an embodiment, the light-field display device may generate a 3D stereoscopic image by generating a light field by using the display module 100 that displays a 2D image and the optical member 200 that converts the 2D image into a 3D image and displays it. As will be described later, the light-field display device allows an image display light generated in each of the pixels in the display module 100 to form a light field directed to a particular direction (e.g., a particular viewing angle and/or a particular viewpoint) by stereoscopic lenses, pinholes, barriers, or the like included in the optical member 200. In this manner, 3D stereoscopic image information associated with the particular direction can be provided to the viewer.

The display module 100 may include a display panel 110 and a display driver 120.

The display panel 110 may include a display area DA and a non-display areas NDA. The display area DA may include data lines, scan lines, supply voltage lines, and a plurality of pixels connected to the data lines and scan lines. In some embodiments, the scan lines may be extended in the first direction (e.g., the X-axis direction) and be spaced apart from one another in the second direction (e.g., the Y-axis direction). The data lines and the supply voltage lines may be extended in the second direction (e.g., the Y-axis direction) and be spaced from one another in the first direction (e.g., the X-axis direction).

Each pixel (or unit pixel) formed and arranged in the display panel 110 includes the minimum number of sub-pixels capable of emitting white light. In some embodiments, each pixel may include three sub-pixels emitting red, green and blue light, respectively. Each of the pixels arranged sequentially and repeatedly may be connected to at least one scan line, a data line, and a supply voltage line. Each of the sub-pixels may include thin-film transistors including a driving transistor and at least one switching transistor, a light-emitting element, and a capacitor. When a scan signal is applied from a scan line, each of the pixels receives a data voltage from a data line and supplies a driving current to the light-emitting element according to the data voltage applied to the gate electrode, so that light can be emitted.

Herein, the pixels of the display panel 110 (e.g., the unit pixels) display 2D multi-view images according to the order in which the display driver 120 provides image data. The multi-view images include n view images, where n is a natural number greater than or equal to two. Such n view images are generated by capturing images of an object with n cameras spaced apart from one another by the distance between a person's eyes.

The display panel 110 may display multi-view images in units of n pixels during an image display period. In some embodiments, the display panel 110 may display multi-view images in units of two pixels. For example, two pixels of the display panel 110 may display a multi-view image including two view images. In an embodiment, the display panel 110 may display a multi-view image in units of time-division frames (or sub-frames) according to the time-division driving of the display driver 120. Multi-view images may be displayed in units of two pixels for each time-division frame. A time-division frame is a period that divides one frame into ½ or ⅓ sub-frames.

The non-display area NDA may be disposed at the edge of the display panel 110 to surround the display area DA in a plan view. The term “in a plan view” and “on a plane” may each refer to when viewed from above. The non-display area NDA may include a scan driver that applies scan signals to scan lines, and pads connected to the display driver 120. In some embodiments, the display driver 120 may be disposed on one side of the non-display area NDA (e.g., in a plan view), and the pads may be disposed on one edge of the non-display area NDA on which the display driver 120 is disposed.

The display driver 120 may output control signals and image data voltages for driving the display panel 110 in units of at least one frame or at least one time-division frame (or sub-frame). In some embodiments, the display driver 120 may supply image data voltages to the data lines in units of at least one time-division frame (or sub-frame). The display driver 120 supplies supply voltage to the supply voltage line, and may supply scan control signals to the scan driver.

In an embodiment, the display driver 120 may be implemented as an integrated circuit (IC) and may be disposed in the non-display area NDA of the display panel 110 by a chip on glass (COG) technique, a chip on plastic (COP) technique, or an ultrasonic bonding. For another example, the display driver 120 may be mounted on a circuit board and connected to the pads of the display panel 110.

The optical member 200 may be disposed on the front side of the display panel 110 or the display module 100. In an embodiment, the optical member 200 may be attached to one surface (e.g., a first surface) of the display panel 110 or the display area DA through an adhesive member. In an embodiment, the optical member 200 may be attached to the front surface of the display module 100 by a panel bonding apparatus.

The optical member 200 may provide 3D images by refracting lights displayed by the display area DA of the display panel 110. The optical member 200 may guide light paths of the display panel 110 so that the view images are provided to their respective view areas.

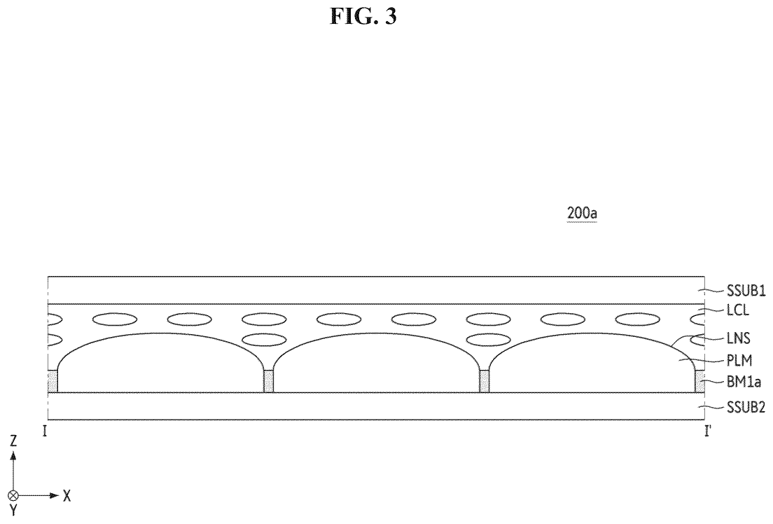

The optical member 200 will be described in detail later with reference to FIGS. 3 to 6.

FIG. 3 is a cross-sectional view for illustrating the optical member taken along line I-I′ of FIG. 1.

Referring to FIG. 3, in an embodiment an optical member 200a may include a first base substrate SSUB1, a second base substrate SSUB2, a plurality of lenses LNS, a plurality of first light-blocking members BM1a, and a liquid-crystal layer LCL.

The first base substrate SSUB1 and the second base substrate SSUB2 may face each other (e.g., in the Z-axis direction). The first base substrate SSUB1 and the second base substrate SSUB2 may extend in the first direction (e.g., the X-axis direction) and the second direction (e.g., the Y-axis direction). The first base substrate SSUB1 and the second base substrate SSUB2 may include a transparent material. The first base substrate SSUB1 and the second base substrate SSUB2 may transmit light.

The plurality of lenses LNS may be arranged on (e.g., disposed directly thereon) a surface of the second base substrate SSUB2. For example, the first base substrate SSUB1 may be disposed on a first side of the plurality of lenses LNS and the second base substrate SSUB2 may be disposed on an opposite second side of the plurality of lenses LNS. In an embodiment, the plurality of lenses LNS may directly contact an upper surface of the second base substrate SSUB2 and be spaced apart (e.g., in the Z-axis direction) from a lower surface of the first base substrate SSUB1 by the liquid-crystal layer LCL. The liquid-crystal layer LCL may directly contact the lower surface of the first base substrate SSUB1. In some embodiments, the plurality of lenses LNS may include a plurality of lens surfaces that are convex in a third direction (e.g., the Z-axis direction). The plurality of lenses LNS may include a polymer layer PLM including a polymer.

The plurality of first light-blocking members BM1a may be arranged between the plurality of lenses LNS (e.g., in a plan view). In some embodiments, the plurality of first light-blocking members BM1a may be formed in a rectangular shape in the thickness direction of the base substrate (e.g., in a cross-section view). The plurality of first light-blocking members BM1a may include a material that absorbs visible light. In some embodiments, the plurality of first light-blocking members BM1a may include a resin material including a metal material, a pigment, or a dye. The plurality of first light-blocking members BM1a can prevent lights displayed on the display panel 110 from being refracted at the edges of each of the plurality of lenses LNS to the adjacent lenses LNS on the opposite sides. In this manner, it is possible to reduce 3D crosstalk.

The liquid-crystal layer LCL may be located over the plurality of lenses LNS and the plurality of first light-blocking members BM1a. The liquid-crystal layer LCL may include liquid crystals, which is a material having refractive index anisotropy.

In some embodiments, when no voltage is applied to one side (e.g., a first side) where the liquid-crystal layer LCL and the first base substrate SSUB1 face each other and the other side (e.g., an opposite second side) where the liquid-crystal layer LCL and the second base substrate SSUB2 face each other, the major axis of the liquid crystals may be aligned in the first direction (e.g., the X-axis direction).

When a voltage is applied to the side (e.g., a first side) where the liquid-crystal layer LCL and the first base substrate SSUB1 face each other and the other side (e.g., the opposite second side) where the liquid-crystal layer LCL and the second base substrate SSUB2 face each other, the major axis of the liquid crystals may be aligned in the third direction (e.g., the Z-axis direction).

Depending on the polarization direction of the light displayed on the display panel 110 and the alignment direction of the liquid crystals, the light displayed on the display panel 110 may be refracted in the liquid-crystal layer LCL or may pass through it without being refracted. In some embodiments, when the polarization direction of light displayed on the display panel 110 is the first direction (e.g., the X-axis direction) and the major axis of the liquid crystals is aligned in the first direction (e.g., the X-axis direction), the light displayed on the display panel 110 may be refracted at the interface between the plurality of lenses LNS and the liquid-crystal layer LCL. For another example, when the polarization direction of light displayed on the display panel 110 is the first direction (e.g., the X-axis direction) and the major axis of the liquid crystals is aligned in the third direction (e.g., the z-axis direction), the light displayed on the display panel 110 may not be refracted at the interface between the plurality of lenses LNS and the liquid-crystal layer LCL but may pass through it.

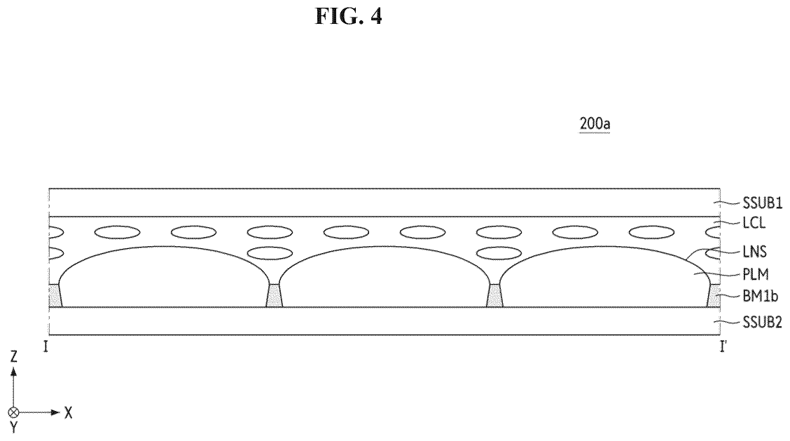

FIG. 4 is a cross-sectional view for illustrating the optical member taken along line I-I′ of FIG. 1. The following description will focus on differences and the redundant description will be omitted.

Referring to FIG. 4, in an embodiment an optical member 200a may include a first base substrate SSUB1, a second base substrate SSUB2, a plurality of lenses LNS, a plurality of first light-blocking members BM1b, and a liquid-crystal layer LCL. The first base substrate SSUB1, the second base substrate SSUB2, the plurality of lenses LNS and the liquid-crystal layer LCL may be substantially identical to those described above with reference to FIG. 3 and a repeated description may be omitted for economy of explanation.

The plurality of first light-blocking members BM1b may be arranged between the plurality of lenses LNS. In some embodiments, the length of the lower surface of the plurality of first light-blocking members BM1b in the first direction (e.g., the X-axis direction) may be larger than the length of the upper surface in the first direction (e.g., the x-axis direction). Although the side surfaces (e.g., lateral side surfaces) of the first light-blocking members BM1b are flat surfaces in the drawings, embodiments of the present disclosure are not necessarily limited thereto. For example, in some embodiments the side surfaces of the first light-blocking members BM1b may be curved surfaces.

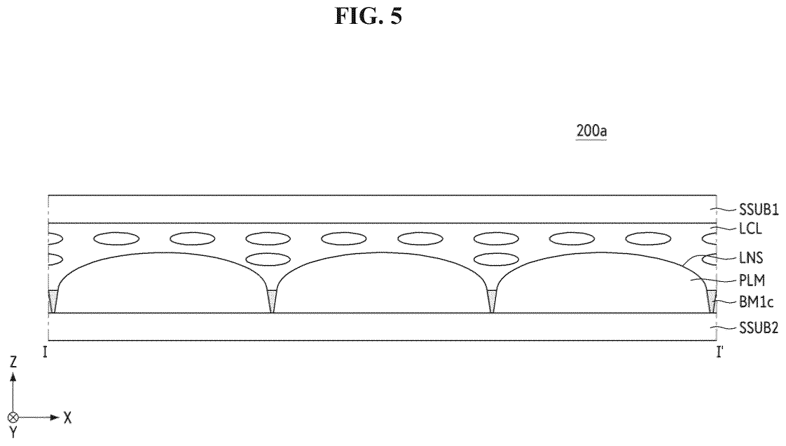

FIG. 5 is a cross-sectional view for illustrating the optical member taken along line I-I′ of FIG. 1. The following description will focus on differences and the redundant description will be omitted for economy of explanation.

Referring to FIG. 5, in an embodiment an optical member 200a may include a first base substrate SSUB1, a second base substrate SSUB2, a plurality of lenses LNS, a plurality of first light-blocking members BM1c, and a liquid-crystal layer LCL. The first base substrate SSUB1, the second base substrate SSUB2, the plurality of lenses LNS and the liquid-crystal layer LCL may be substantially identical to those described above with reference to FIG. 3 and a repeated description may be omitted for economy of explanation.

The plurality of first light-blocking members BM1c may be arranged between the plurality of lenses LNS. In some embodiments, the length of the upper surface of the plurality of first light-blocking members BM1c in the first direction (e.g., the X-axis direction) may be larger than the length of the lower surface in the first direction (e.g., the X-axis direction). Although the side surfaces (e.g., lateral side surfaces) of the first light-blocking members BM1c are flat surfaces in the drawings, embodiments of the present disclosure are not necessarily limited thereto. The side surfaces of the first light-blocking members BM1c may be curved surfaces.

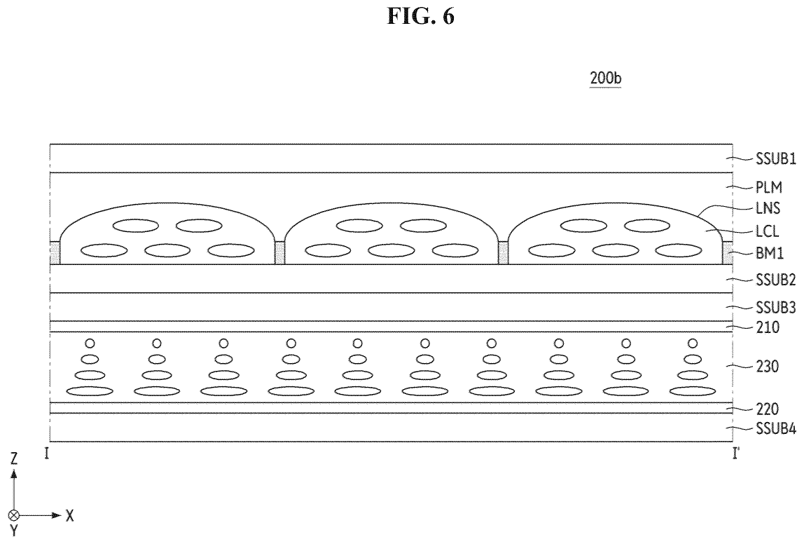

FIG. 6 is a cross-sectional view for illustrating the optical member taken along line I-I′ of FIG. 1. The following description will focus on differences and the redundant description will be omitted for economy of explanation.

Referring to FIG. 6, in an embodiment the optical member 200b may include a first base substrate SSUB1, a second base substrate SSUB2, a plurality of lenses LNS, a polymer layer PLM, a plurality of first light-blocking members BM1, and a polarization controller.

In an embodiment, the polarization controller may include a third base substrate SSUB3, a fourth base substrate SSUB4, a first driving electrode 210, a second driving electrode 220, and driving liquid crystals 230. The polarization controller may be disposed directly on a lower surface of the second base substrate SSUB2. The polarization controller may output light incident from the display panel 110 as one of the first polarized light and the second polarized light.

The first to fourth base substrates SSUB1 to SSUB4 may extend in the first direction (e.g., the X-axis direction) and the second direction (e.g., the Y-axis direction). The first to fourth base substrates SSUB1 to SSUB4 may be arranged parallel to one another. The first to fourth base substrates SSUB1 to SSUB4 may include a transparent material. The first to fourth base substrates SSUB1 to SSUB4 may transmit light.

A plurality of lenses LNS and a plurality of first light-blocking members BM1 may be arranged on a surface of the second base substrate SSUB2 (e.g., disposed directly thereon in the Z-axis direction). The plurality of lenses LNS may include a plurality of lens surfaces that are convex in the third direction (e.g., the Z-axis direction). The plurality of lenses LNS may include a liquid-crystal layer LCL including liquid crystals, which is a material having refractive index anisotropy.

The plurality of first light-blocking members BM1 may be arranged between the plurality of lenses LNS (e.g., in the X-axis direction). The first light-blocking members BM1 may absorb light directed to the edges of the plurality of lenses LNS. By doing so, it is possible to block the light from being refracted at the edges of the plurality of lenses LNS to the adjacent lenses LNS on the opposite sides, thereby preventing the view images from being provided to other view areas.

The polymer layer PLM may be located over the plurality of lenses LNS and the plurality of first light-blocking members BM1. The refractive index of the polymer layer PLM may be equal to the refractive index of the liquid crystals of the liquid-crystal layer LCL in the minor axis direction. Accordingly, depending on the polarization direction of the light passing through the second base substrate SSUB2, the light may be or may not be refracted at the interface between the lenses LNS and the polymer layer PLM.

The opposite surface of the second base substrate SSUB2 may be in direct contact with a surface of the third base substrate SSUB3.

The opposite surface of the third base substrate SSUB3 may face a surface of the fourth base substrate SSUB4. A first driving electrode 210 may be arranged on (e.g., disposed directly thereon) the opposite surface of the third base substrate SSUB3. The first driving electrode 210 may receive a driving voltage from the display driver 120.

The second driving electrode 220 may be arranged on (e.g., disposed directly thereon) the surface of the fourth base substrate SSUB4. The second driving electrode 220 may be parallel to the first driving electrode 210. The shape of the second driving electrode 220 may conform to the shape of the first driving electrode 210. The second driving electrode 220 may receive a driving voltage from the display driver 120.

The driving liquid crystals 230 may be arranged between the first driving electrode 210 and the second driving electrode 220 (e.g., in the Z-axis direction). The driving liquid crystals 230 may include liquid crystals which is a material having refractive index anisotropy. The arrangement of the driving liquid crystals 230 may vary depending on the voltage difference between the first driving electrode 210 and the second driving electrode 220.

In some embodiments, if the voltage difference between the first driving electrode 210 and the second driving electrode 220 is less than or equal to a value (e.g., a first value), the major axis of the liquid crystals may be aligned in the first direction (e.g., the X-axis direction) at the lower portion of the driving liquid crystals 230. The major axis of the liquid crystals may be aligned in the second direction (e.g., the Y-axis direction) at the upper portion of the driving liquid crystals 230. The major axis of the liquid crystals may gradually change between the upper and lower portions of the driving liquid crystals 230. In some embodiments, the driving liquid crystals 230 may be TN (twisted nematic) liquid crystals.

When the polarization direction of the light displayed on the display panel 110 is the first direction (e.g., the X-axis direction), the light displayed on the display panel 110 may pass through the driving liquid crystals 230 and the polarization direction may gradually change from the first direction (e.g., the X-axis direction) to the second direction (e.g., the Y-axis direction).

Since the light has the polarization in the second direction (e.g., the Y-axis direction), and the refractive index in the minor axis direction, such as the refractive index of the liquid-crystal layer LCL in the second direction (e.g., the Y-axis direction) is equal to the refractive index of the polymer layer PLM, the light may pass through without being refracted at the interface between the liquid-crystal layer LCL and the polymer layer PLM.

For another example, if the voltage difference between the first driving electrode 210 and the second driving electrode 220 is greater than the value (e.g., the first value), the major axis of the liquid crystals of the driving liquid crystals 230 may be aligned in the third direction (e.g., the Z-axis direction).

When the polarization direction of the light displayed on the display panel 110 is the first direction (e.g., the X-axis direction), the polarization direction of the light displayed on the display panel 110 may remain in the first direction (e.g., the X-axis direction) through the driving liquid crystals 230.

Since the light has the polarization in the first direction (e.g., the X-axis direction), and the refractive index in the major axis direction, such as the refractive index of the liquid-crystal layer LCL in the first direction (e.g., the X-axis direction) is different from the refractive index of the polymer layer PLM, the light may be refracted at the interface between the liquid-crystal layer LCL and the polymer layer PLM.

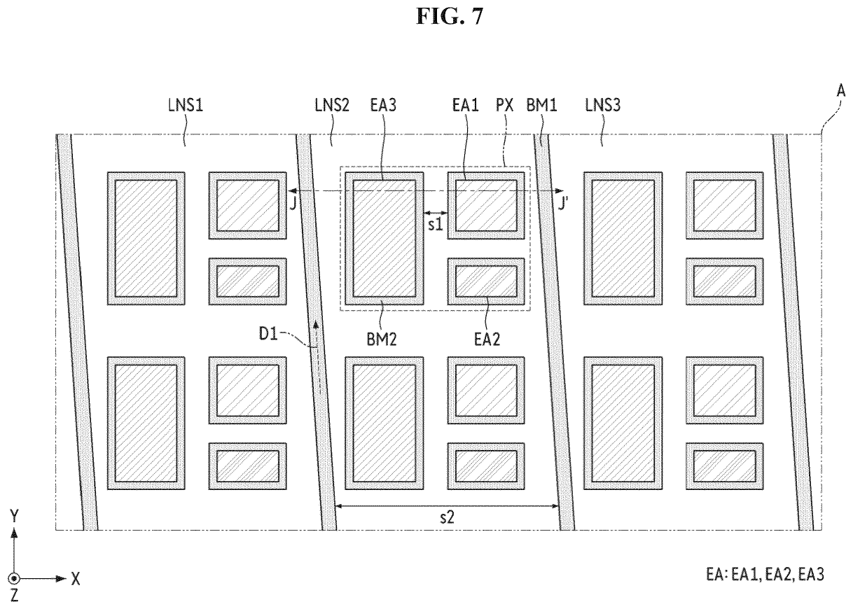

FIG. 7 is an enlarged view of portion A of FIG. 2.

Referring to FIG. 7, in an embodiment the display device 290 may include first light-emitting areas EA1, second light-emitting areas EA2, third light-emitting areas EA3, a plurality of first light-blocking members BM1, a plurality of second light-blocking members BM2, and a plurality of lenses LNS1, LNS2 and LNS3.

The first light-emitting areas EA1 may emit light of a first color. In some embodiments, the first light-emitting areas EA1 may be red light-emitting areas.

The second light-emitting areas EA2 may emit light of a second color. In some embodiments, the second light-emitting areas EA2 may be green light-emitting areas.

The third light-emitting areas EA3 may emit light of a third color. In some embodiments, the third light-emitting areas EA3 may be blue light-emitting areas.

In the example shown in FIG. 7, the size (e.g., area in a plan view) of the second light-emitting areas EA2 is less than the size (e.g., area in a plan view) of the first light-emitting areas EA1, and the size (e.g., area in a plan view) of the first light-emitting areas EA1 is less than the size (e.g., area in a plan view) of the third light-emitting areas EA3. It should be understood, however, that embodiments of the present disclosure are not necessarily limited thereto. The size of the first light-emitting areas EA1, the size of the second light-emitting areas EA2 and the size of the third light-emitting areas EA3 may be all equal or may be different from one another in various ways.

In some embodiments, a single pixel PX may include one first light-emitting area EA1, one second light-emitting area EA2 and one third light-emitting area EA3. The first light-emitting areas EA1 and the second light-emitting areas EA2 may be adjacent to each other in the second direction (e.g., the Y-axis direction). The first light-emitting areas EA1 and the third light-emitting areas EA3 may be adjacent to each other in the first direction (e.g., the X-axis direction). The second light-emitting areas EA2 and the third light-emitting areas EA3 may be adjacent to each other in the first direction (e.g., the X-axis direction). It should be understood, however, that embodiments of the present disclosure are not necessarily limited thereto. The shape and configuration of the pixels PX of the display device 290 may be modified in some embodiments. For another example, a single pixel PX may include one first light-emitting area EA1, two second light-emitting areas EA2 and one third light-emitting area EA3.

Although the light-emitting areas EA1, EA2 and EA3 have a rectangular shape (e.g., in a plan view) in the drawings, the shape of the light-emitting areas EA1, EA2 and EA3 (e.g., in a plan view) may be modified to a variety of shapes, such as a circular shape, an elliptical shape and a convex polygonal shape in some implementations.

The second light-blocking members BM2 may surround the first light-emitting areas EA1, the second light-emitting areas EA2, and the third light-emitting areas EA3. For example, in an embodiment the second light-blocking members BM2 may completely surround the first light-emitting areas EA1, the second light-emitting areas EA2, and the third light-emitting areas EA3 (e.g., in a plan view). A second light-blocking member BM2 may be arranged on the border of each of the first light-emitting areas EA1, the second light-emitting areas EA2 and the third light-emitting areas EA3. The second light-blocking members BM2 may be associated with the light-emitting areas EA1, EA2 and EA3, respectively.

The shape of the second light-blocking members BM2 may be modified to conform to the shapes of the first to third light-emitting areas EA1, EA2 and EA3. In the drawings, the second light-blocking members BM2 have a rectangular frame shape conforming to the shapes of the first to third light-emitting areas EA1, EA2 and EA3. As another example, if the first to third light-emitting areas EA1, EA2 and EA3 have circular shapes when viewed from the top, the second light-blocking members BM2 may be formed in a circular frame shape surrounding (e.g., completely surrounding) the borders of the light-emitting areas EA1, EA2 and EA3.

In an embodiment, the second light-blocking members BM2 may be formed only at the borders of the light-emitting areas EA1, EA2 and EA3, and the second light-blocking members BM2 may be spaced apart from each other (e.g., in a plan view). In some embodiments, the minimum distance in the first direction (e.g., the X-axis direction) between the second light-blocking member BM2 surrounding the third light-emitting area EA3 and the second light-blocking member BM2 surrounding the first light-emitting area EA1 may be a first minimum distance s1. For example, the first minimum distance s1 may be a minimum distance (e.g. in the X-axis direction) between second light-blocking members BM2 adjacent to each other (e.g., immediately adjacent to each other) in the X-axis direction. In an embodiment, the first minimum distance s1 may be greater than zero. In this manner, the area of second light-blocking members BM2 that is visible to the user can be reduced.

The plurality of first light-blocking members BM1 may be arranged between the plurality of lenses LNS1, LNS2 and LNS3 (e.g., in a plan view). In an embodiment, the plurality of first light-blocking members BM1 may extend in a fourth direction D1. The fourth direction D1 may refer to a direction that intersects (e.g., crosses) the first direction (e.g., the X-axis direction) and the second direction (e.g., the Y-axis direction) on the same plane as the first direction (e.g., the X-axis direction) and the second direction (e.g., the Y-axis direction). For example, the fourth direction D1 may be perpendicular to the Z-axis direction. The minimum distance in the X-axis direction between first light-blocking members BM1 adjacent to each other in the X-axis direction (e.g., immediately adjacent to each other) of the plurality of first light-blocking members BM1 may be a second minimum distance s2.

In an embodiment, the plurality of lenses LNS1, LNS2 and LNS3 may also extend in the fourth direction D1. Accordingly, a view area may be determined as the extension direction (e.g., the fourth direction D1) of the plurality of lenses LNS1, LNS2 and LNS3 intersects the arrangement directions (e.g., the first direction and the second direction) of the light-emitting areas EA1, EA2 and EA3.

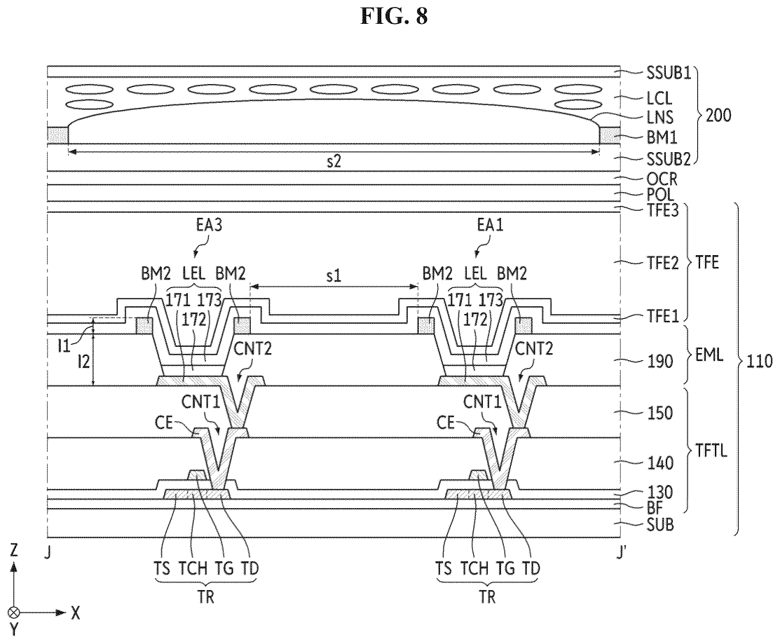

FIG. 8 is a cross-sectional view of the display device, taken along line J-J′ of FIG. 7. The following description will focus on differences and the redundant description may be omitted for economy of explanation.

Although the optical member 200a of FIG. 3 is depicted in FIG. 8 as an example, the optical member 200a of FIG. 4, the optical member 200a of FIG. 5, or the optical member 200b of FIG. 6 may also be applied. Here, for convenience of explanation, the optical member 200 in the drawings may represent any one of the optical members 200a of FIGS. 3 to 5 and the optical member 200b of FIG. 6, and the first light-blocking member BM1 in the drawings may represent any one of the first light-blocking member BM1a of FIG. 3, the first light-blocking member BM1b of FIG. 4, and the first light-blocking member BM1c of FIG. 5.

Referring to FIG. 8, in an embodiment the display panel 110 may include a substrate SUB, a thin-film transistor layer TFTL, an emission material layer EML, an encapsulation layer TFE and a polarization layer POL. In an embodiment, a coupling member OCR that couples the display panel 110 with the optical member 200 may be disposed between the display panel 110 and the optical member 200 (e.g., in the Z-axis direction). In an embodiment, the coupling member OCR may include a transparent adhesive material such as an optically clear adhesive (OCA) film and an optically clear resin (OCR).

The substrate SUB may have rigidity to support an element formed on the substrate SUB. In some embodiments, the substrate SUB may be a glass substrate or a plastic substrate such as polyethylene terephthalate (PET).

The thin-film transistor layer TFTL may be located on the substrate SUB (e.g., in the Z-axis direction). The thin-film transistor layer TFTL may adjust the brightness of the display device 290. The thin-film transistor layer TFTL may include transistors.

In an embodiment, the thin-film transistor layer TFTL may include a buffer film BF, a plurality of thin-film transistors TR, a gate insulator 130, a connection electrode CE, a first planarization layer 140 and a second planarization layer 150. Each of the thin-film transistors TR may include a channel TCH, a gate electrode TG, a source electrode TS, and a drain electrode TD.

The channel TCH may be a region overlapping with the gate electrode TG of the thin-film transistor TR in the third direction (e.g., the Z-axis direction), which is the thickness direction of the substrate SUB. The source electrode TS may be disposed on a side of the channel TCH, and the drain electrode TD may be disposed on the opposite side of the channel TCH. The source electrode TS and the drain electrode TD may be regions that do not overlap with the gate electrode TG in the third direction (e.g., in the Zz-axis direction). The source electrode TS and the drain electrode TD may be regions having conductivity by doping ions in a silicon semiconductor or an oxide semiconductor.

The gate insulator 130 may be disposed on (e.g., disposed directly thereon) the channel TCH, the source electrode TS, the drain electrode TD, and the buffer film BF. The gate insulator 130 may include an inorganic layer, in some embodiments, a silicon nitride layer, a silicon oxynitride layer, a silicon oxide layer, a titanium oxide layer, or an aluminum oxide layer.

The gate electrode TG of each of the thin-film transistors TR may be arranged on the gate insulator 130 (e.g., disposed directly thereon in the Z-axis direction). In an embodiment, the gate electrode TG may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first planarization layer 140 may be disposed on (e.g., disposed directly thereon) the gate electrode TG and the gate insulator 130. The first planarization layer 140 may provide a flat surface over the thin-film transistor TR having different heights. In an embodiment, the first planarization layer 140 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The connection electrode CE may be located on the first planarization layer 140 (e.g., disposed directly thereon in the Z-axis direction). In an embodiment, the connection electrode CE may be connected to the drain electrode TD through a first contact hole CNT1 penetrating the first planarization layer 140. In an embodiment, the connection electrodes CE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization layer 150 may be located on (e.g., disposed directly thereon) the connection electrodes CE and the first planarization layer 140. In an embodiment, the second planarization layer 150 may be formed as an organic layer such as an acrylic resin, an epoxy resin, a phenolic resin, a polyamide resin and a polyimide resin.

The emission material layer EML may be located on the thin-film transistor layer TFTL (e.g., disposed directly thereon in the Z-axis direction). The emission material layer EML may include first to third light-emitting areas EA1, EA2 and EA3. The emission material layer EML may include a plurality of light-emitting elements LEL, a plurality of second light-blocking members BM2, and a pixel-defining layer 190.

In an embodiment, each of the light-emitting elements LEL may be, but is not necessarily limited to, an organic light-emitting diode including a pixel electrode 171, a light-emitting layer 172 and a common electrode 173.

The pixel electrode 171 may be disposed on the second planarization layer 150 (e.g., in the Z-axis direction). In an embodiment, the pixel electrode 171 may be connected to (e.g., directly connected thereto) the connection electrode CE through a second contact hole CNT2 penetrating the second planarization layer 150.

In the top-emission structure in which light exits from the light-emitting layer 172 towards the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

The pixel-defining layer 190 may be located on (e.g., disposed directly thereon) the second planarization layer 150 to cover the edges of each of the pixel electrodes 171 and expose a portion (e.g., a central portion) of each of the pixel electrodes 171 to define the light-emitting areas EA1, EA2 and EA3. In an embodiment, the pixel-defining layer 190 may be formed of an organic layer such as an acrylic resin, an epoxy resin, a phenolic resin, a polyamide resin and a polyimide resin.

In each of the light-emitting areas EA1, EA2 and EA3 the pixel electrode 171, the light-emitting layer 172 and the common electrode 173 are stacked on one another sequentially (e.g., in the Z-axis direction), so that holes from the pixel electrode 171 and electrons from the common electrode 173 are recombined in the light-emitting layer 172 to emit light.

The light-emitting layer 172 may be located on the pixel electrode 171 (e.g., in the Z-axis direction). The light-emitting layer 172 may include an organic material to emit light of a particular color. In some embodiments, the light-emitting layer 172 may include a hole transporting layer, an organic material layer, and an electron transporting layer.

The common electrode 173 may be located on the light-emitting layer 172 (e.g., in the Z-axis direction). The common electrode 173 may cover the light-emitting layer 172. In an embodiment, the common electrode 173 may be a common layer formed across (e.g., commonly disposed in) the light-emitting areas EA. In an embodiment, a capping layer may be formed on the common electrode 173.

In the top-emission organic light-emitting diode, the common electrode 173 may include a transparent conductive material (TCP) such as ITO and IZO or a semi-transmissive conductive material such as magnesium (Mg), silver (Ag) and an alloy of magnesium (Mg) and silver (Ag) that can transmit light. When the common electrode 173 is made of a semi-transmissive metal material, the light extraction efficiency can be increased by using microcavities.

The second light-blocking members BM2 may be arranged on the pixel-defining layer 190. For example, in an embodiment, the second light-blocking members BM2 may be disposed on the pixel-defining layer 190 (e.g., disposed directly thereon in the Z-axis direction) and may be arranged between (e.g., directly therebetween) the pixel-defining layer 190 and the common electrode 173. The plurality of second light-blocking members BM2 may include a material that absorbs visible light. In some embodiments, the plurality of second light-blocking members BM2 may include a resin material including a metal material, a pigment, or a dye. The plurality of second light-blocking members BM2 can prevent light emitted from the light-emitting areas EA1, EA2 and EA3 from being directed to the edges of the plurality of lenses LNS. In this manner, it is possible to prevent light from being refracted at the edges of the lenses LNS to the adjacent lenses LNS on the opposite sides, so that 3D crosstalk can be reduced.

The second light-blocking members BM2 may not overlap with the light-emitting layer 172 in the third direction (e.g., the Z-axis direction).

In some embodiments, the plurality of second light-blocking members BM2 may not overlap with the plurality of first light-blocking members BM1 in the third direction (e.g., the Z-axis direction). In an embodiment, the first minimum distance s1 between adjacent (e.g., immediately adjacent in the X-axis direction) second light-blocking members BM2 in the first direction (e.g., the X-axis direction) may be less than the second minimum distance s2 between adjacent (e.g., immediately adjacent in the X-axis direction) first light-blocking members BM1 in the first direction (e.g., the X-axis direction). In some embodiments, the greatest common divisor of the first minimum distance s1 and the second minimum distance s2 may be 1.

The height l1 of the second light-blocking members BM2 may be less than the height l2 of the pixel-defining layer 190. The heights l1 and l2 of the second light-blocking members BM2 and the pixel-defining layer 190 may be respective lengths in the Z-axis direction which is a thickness direction of the substrate SUB. Accordingly, the light emitted from the light-emitting areas EA1, EA2 and EA3 at a large angle with the third direction (e.g., the Z-axis direction) can be effectively blocked by the second light blocking members BM2, while the light emitted from the light-emitting areas EA1, EA2 and EA3 at a small angle with the third direction (e.g., the Z-axis direction) may not be blocked by the second light blocking members BM2.

The encapsulation layer TFE may be located over (e.g., disposed directly thereon) the emission material layer EML. In an embodiment, the encapsulation layer TFE includes at least one inorganic film and at least one organic film for encapsulating the emission material layer EML. In some embodiments, the encapsulation layer TFE may include a first inorganic encapsulation layer TFE1 and a second inorganic encapsulation layer TFE3 that serve to prevent oxygen or moisture from permeating into the emission material layer EML. In some embodiments, the encapsulation layer TFE may include an organic encapsulation layer TFE2 that protects the emission material layer EML from particles such as dust.

In some embodiments, the first inorganic encapsulation layer TFE1, the organic encapsulation layer TFE2 and the second inorganic encapsulation layer TFE3 of the encapsulation layer TFE may be stacked on one another sequentially (e.g., in the Z-axis direction).

In an embodiment, the first inorganic encapsulation layer TFE1 and the second inorganic encapsulation layer TFE3 may be made up of multiple layers in which one or more inorganic layers of a silicon nitride layer, a silicon oxynitride layer, a silicon oxide layer, a titanium oxide layer and an aluminum oxide layer are alternately stacked on one another (e.g., in the Z-axis direction). In an embodiment, the organic encapsulation film TFE2 may be an organic layer such as an acrylic resin, an epoxy resin, a phenolic resin, a polyamide resin, a polyimide resin, etc.

The polarization layer POL may be located on the encapsulation layer TFE (e.g., disposed directly thereon in the Z-axis direction). The polarization layer POL may transmit light vibrating in a particular direction and block light vibrating in a direction different from the direction. For convenience of illustration, an example will be described where the polarization layer POL transmits light vibrating in the first direction (e.g., the X-axis direction).

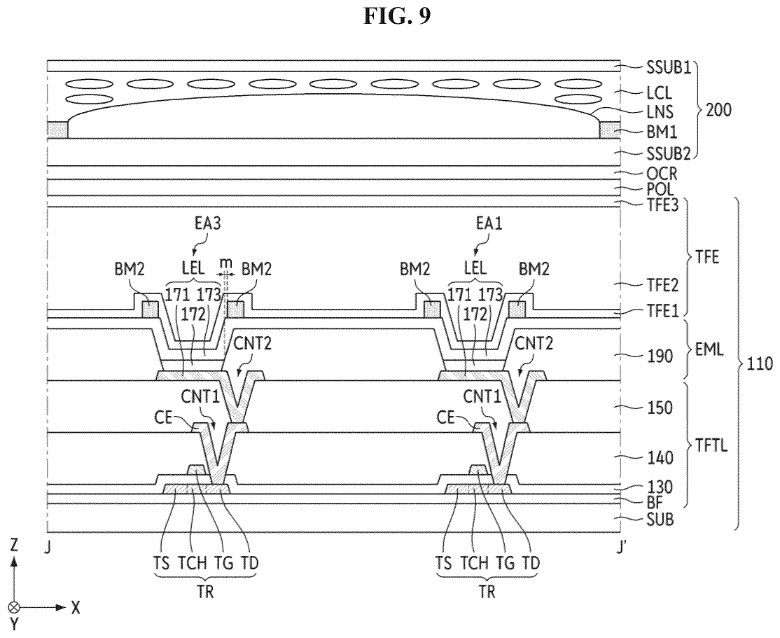

FIG. 9 is a cross-sectional view of the display device, taken along line J-J′ of FIG. 7. The following description will focus on differences and the redundant description will be omitted for economy of explanation.

Referring to FIG. 9, a plurality of second light-blocking members BM2 may be arranged on the common electrode 173 (e.g., disposed directly thereon in the Z-axis direction). The first inorganic encapsulation layer TFE1 may be arranged on (e.g., disposed directly thereon) the plurality of second light-blocking members BM2. For example, in an embodiment, the second light-blocking members BM2 may be disposed on the common electrode 173 (e.g., disposed directly thereon in the Z-axis direction) and may be arranged between (e.g., directly therebetween) the common electrode 173 and the encapsulation layer TFE, such as the first inorganic encapsulation layer TFE1.

In the third direction (e.g., the Z-axis direction), the plurality of second light-blocking members BM2 may not overlap with the light-emitting areas EA1, EA2 and EA3. In the first direction (e.g., the X-axis direction), the minimum distance (m) between adjacent second-light blocking members BM2 of the plurality of second light-blocking members BM2 and the light-emitting areas EA1, EA2 and EA3, such as edges of the light-emitting areas EA1, EA2 and EA3, may be greater than or equal to zero.

Like in FIG. 8, the height (e.g., length in the Z-axis direction) of the plurality of second light-blocking members BM2 may be less than the height (e.g., length in the Z-axis direction) of the pixel-defining layer 190. The minimum distance between adjacent second light-blocking members BM2 of the plurality of second light-blocking members BM2 in the first direction (e.g., the X-axis direction) may be less than the minimum distance between adjacent first light-blocking members BM1 of the plurality of first light-blocking members BM1 in the first direction (e.g., the X-axis direction). In the third direction (e.g., the Z-axis direction), the plurality of second light-blocking members BM2 may not overlap with the plurality of first light-blocking members BM1.

Although the optical member 200a of FIG. 3 is depicted in FIG. 9 as an example, the optical member 200a of FIG. 4, the optical member 200a of FIG. 5, or the optical member 200b of FIG. 6 may also be applied.

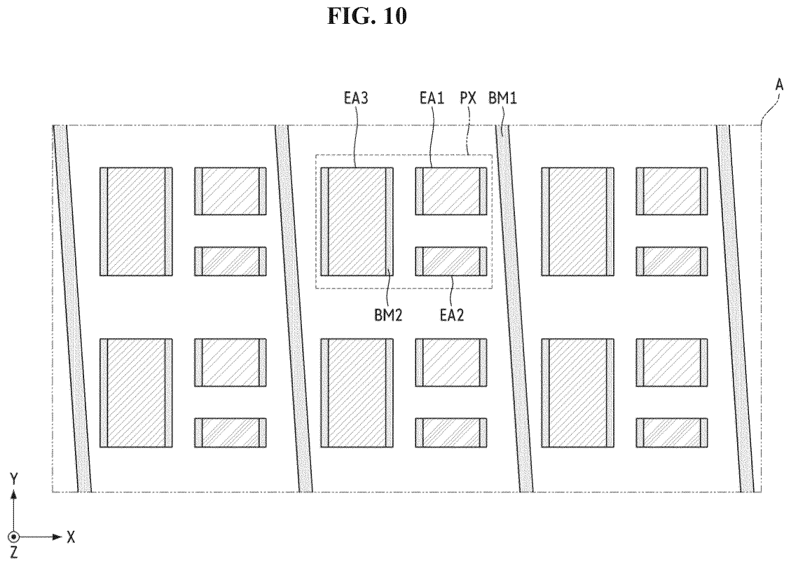

FIG. 10 is an enlarged view of portion A of FIG. 2. The following description will focus on differences and the redundant description may be omitted for economy of explanation.

Referring to FIG. 10, a plurality of second light-blocking members BM2 may be arranged on at least one side of each of the light-emitting areas EA1, EA2 and EA3.

In some embodiments, each of the light-emitting areas EA1, EA2 and EA3 may include the first to fourth sides (e.g., in a plan view). The first side may refer to the left side of each of the light-emitting areas EA1, EA2 and EA3 (e.g., in a plan view). The second side may refer to the right side of each of the light-emitting areas EA1, EA2 and EA3 opposed to the first side (e.g., in the X-axis direction). The third side may refer to the upper side of each of the light-emitting areas EA1, EA2 and EA3 (e.g., in a plan view) that connects an end (e.g., a first end) of the first side with an end (e.g., a first end) of the second side. The fourth side may refer to the lower side of each of the light-emitting areas EA1, EA2 and EA3 (e.g., in a plan view) that connects the other end (e.g., an opposite second end) of the first side with the other end (e.g., an opposite second end) of the second side and is opposed to the third side (e.g., in the Y-axis direction).

In an embodiment, the acute angle formed by the line extended from the first side and the line extended from the first light-blocking member BM1 adjacent to the first side may be less than the acute angle formed by the line extended from the third side and the line extended from the first light-blocking member BM1 adjacent to the third side. In some embodiments, the acute angle formed by the line extended from the second side and the line extended from the first light-blocking member BM1 adjacent to the second side may be less than the acute angle formed by the line extended from the fourth side and the line extended from the first light-blocking member BM1 adjacent to the fourth side.

In an embodiment, the plurality of second light-blocking members BM2 may be solely arranged on the first side and the second side, respectively, of each of the light-emitting areas EA1, EA2 and EA3. The second light-blocking members BM2 may not be arranged on the third side or the fourth side of each of the light-emitting areas EA1, EA2 and EA3.

In some embodiments, the second light-blocking members BM2 may be arranged on the left side and the right side, respectively, of each of the light-emitting areas EA1, EA2 and EA3 (e.g., in a plan view). The second light-blocking members BM2 may not be arranged on the upper side or the lower side of each of the light-emitting areas EA1, EA2 and EA3 (e.g., in a plan view).

Compared with FIG. 7, in FIG. 10, the plurality of second light-blocking members BM2 may be arranged only on the first side and the second side of each of the light-emitting areas EA1, EA2 and EA3, and may not be arranged on the third side or the fourth side of each of the light-emitting areas EA1, EA2 and EA3. Accordingly, the area of the second light-blocking members BM2 that is recognized by a user can be reduced. Incidentally, 3D crosstalk may be generated by light passing through the edges of the plurality of lenses LNS. Therefore, even though the second light-blocking members BM2 are eliminated on the third and fourth sides of each of the light-emitting areas EA1, EA2 and EA3, it is still possible to effectively reduce 3D crosstalk.

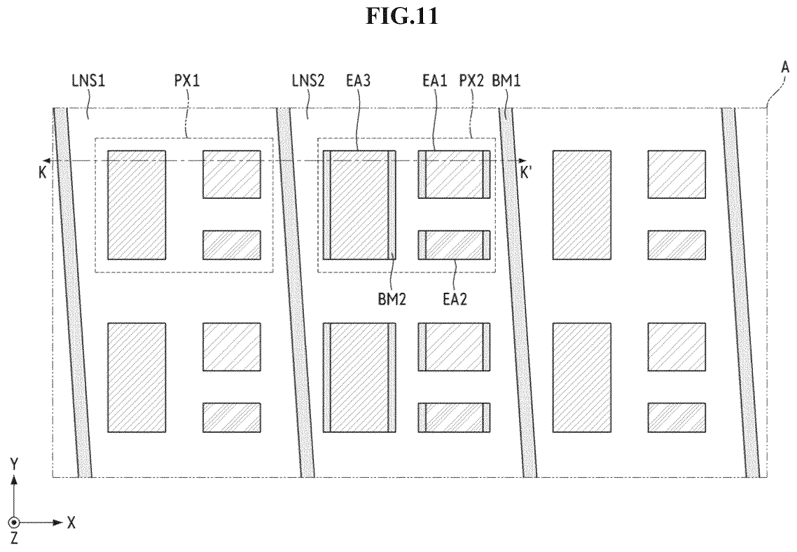

FIG. 11 is an enlarged view of portion A of FIG. 2. The following description will focus on differences and the redundant description may be omitted for economy of explanation.

Referring to FIG. 11, the light-emitting areas EA1, EA2 and EA3 may include a first group of light-emitting areas that emit light in a first period, and a second group of light-emitting areas that emit light in a second period different from the first period.

A first pixel group PX1 may include light-emitting areas of the first group. In an embodiment, the pixels included in the first pixel group PX1 may be turned on in the first period and turned off in the second period.

A second pixel group PX2 may include light-emitting areas of the second group. In an embodiment, the pixels included in the second pixel group PX2 may be turned on in the second period and turned off in the first period.

In an embodiment, the first period may be a period of time in which the display device 290 displays 2D images (e.g., a 2D mode), and the second period may be a period of time in which the display device 290 displays 3D images (e.g., a 3D mode). For example, when the display device 290 is in the 2D mode, only the light-emitting areas EA1, EA2 and EA3 of the first group included in the first pixel group PX1 may emit light, while the light-emitting areas EA1, EA2 and EA3 of the second group included in the second pixel group PX2 may not emit light. When the display device 290 is in the 3D mode, only the light-emitting areas EA1, EA2 and EA3 of the second group included in the second pixel group PX2 may emit light, while the light-emitting areas EA1, EA2 and EA3 of the first group included in the first pixel group PX1 may not emit light.

A plurality of second light-blocking members BM2 may not be arranged on the first to fourth sides of each of the light-emitting areas EA1, EA2 and EA3 of the first group included in the first pixel group PX1.

In an embodiment, the second light-blocking members BM2 may be arranged on at least one side of each of the light-emitting areas EA1, EA2 and EA3 of the second group included in the second pixel group PX2. Although the second light-blocking members BM2 are arranged on the first side and the second side of each of the light-emitting areas EA1, EA2 and EA3 of the second group in the example shown in FIG. 11, embodiments of the present disclosure are not necessarily limited thereto. For example, as shown in an embodiment of FIG. 7, the second light-blocking members BM2 may be arranged on the first side to the fourth side of each of the light-emitting areas EA1, EA2 and EA3 of the second group.

Since the first pixel group PX1 operates in the 2D mode, lights emitted from the light-emitting areas EA1, EA2 and EA3 of the first group do not implement a multi-view image. Therefore, 3D crosstalk does not occur when the first pixel group PX1 operates, and thus a plurality of second light-blocking members BM2 may not be arranged in the light-emitting areas EA1, EA2 and EA3 of the first group. Accordingly, the second light-blocking members BM2 may not be arranged at the borders of the light-emitting areas EA1, EA2 and EA3 of the first group. In this manner, the area of the second light-blocking members BM2 that is recognized by a user can be reduced.

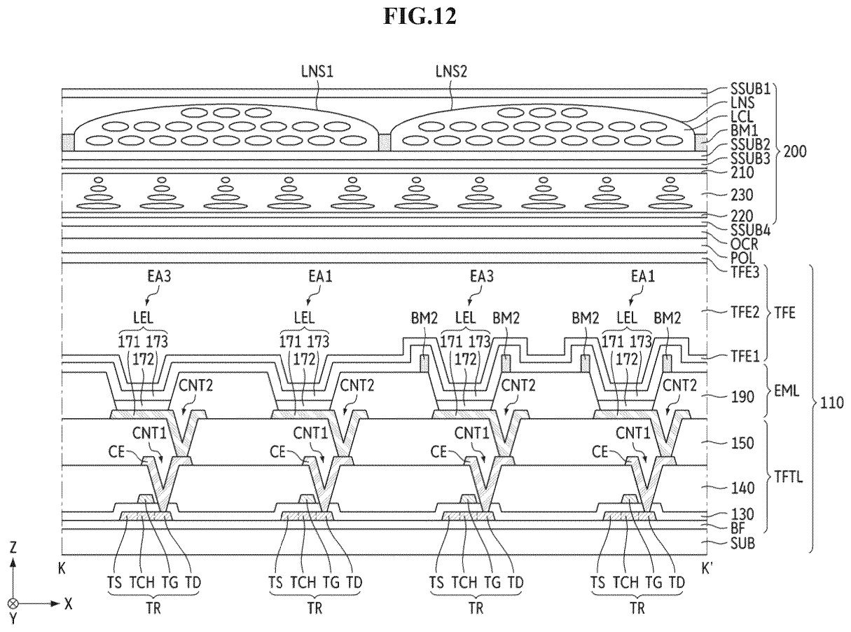

FIG. 12 is a cross-sectional view of the display device, taken along line K-K′ of FIG. 11. The following description will focus on differences and the redundant description will be omitted.

Although the display device 290 includes the optical member 200b described above with reference to FIG. 6 in the example shown in FIG. 12, embodiments of the present disclosure are not necessarily limited thereto. The display device 290 may include the optical member 200a described above with reference to one of FIGS. 3 to 5.

FIG. 12 shows the first light-emitting area EA1 on the left side and the third light-emitting area EA3 on the left side among the light-emitting areas EA1, EA2 and EA3 of the first group included in the first pixel group PX1. The second light-emitting area EA2 among the light-emitting areas EA1, EA2 and EA3 of the first group may have substantially the same cross-sectional structure as the first light-emitting area EA1 and the third light-emitting area EA3 among the light-emitting areas EA1, EA2 and EA3 of the first group.

FIG. 12 shows the first light-emitting area EA1 on the right side and the third light-emitting area EA3 on the right side among the light-emitting areas EA1, EA2 and EA3 of the second group included in the second pixel group PX2. The second light-emitting area EA2 among the light-emitting areas EA1, EA2 and EA3 of the second group may have substantially the same cross-sectional structure as the first light-emitting area EA1 and the third light-emitting area EA3 among the light-emitting areas EA1, EA2 and EA3 of the second group.

Referring to FIG. 12, a plurality of second light-blocking members BM2 may not be arranged on the pixel-defining layer 190 associated with the third light-emitting area EA3 on the left side and the first light-emitting area EA1 on the left side included in the first pixel group PX1.

In contrast, a plurality of second light-blocking members BM2 may be arranged on (e.g., disposed directly thereon in the Z-axis direction) the pixel-defining layer 190 associated with the third light-emitting area EA3 on the right side and the first light-emitting area EA1 on the right side included in the second pixel group PX2.

Although the plurality of second light-blocking members BM2 is arranged on the pixel-defining layer 190, such as disposed directly between the pixel-defining layer 190 and the common electrode 173, associated with the light-emitting areas EA1, EA2 and EA3 included in the second pixel group PX2 in the example shown in FIG. 12, embodiments of the present disclosure are not necessarily limited thereto. As described above with reference to FIG. 9, the plurality of second light-blocking members BM2 may also be arranged on the common electrode 173, such as disposed directly between the common electrode 173 and the first inorganic encapsulation layer TFE1 for the light-emitting areas EA1, EA2 and EA3 included in the second pixel group PX2.

The light-emitting areas EA1, EA2 and EA3 of the first group included in the first pixel group PX1 operating in the first period may overlap with a first lens LNS1 in the third direction (e.g., the Z-axis direction). The light-emitting areas EA1, EA2 and EA3 of the second group included in the second pixel group PX2 operating in the second period may overlap with a second lens LNS2 in the third direction (e.g., the Z-axis direction). In some embodiments, the first pixel group PX1 and the second pixel group PX2 may overlap with different lenses among the plurality of lenses LNS.

In the first period (e.g., in the 2D mode), lights emitted from the light-emitting areas EA1, EA2 and EA3 on the left side included in the first pixel group PX1 may pass through the optical member 200 without being refracted by the optical member 200. In this manner, the display device 290 may provide 2D images to the user.

The lights emitted from the light-emitting areas EA1, EA2 and EA3 on the right side included in the second pixel group PX2 in the second period (e.g., in the 3D mode) may be refracted by the optical member 200 and travel to the respective view areas. In this manner, the display device 290 may provide 3D images to the user.

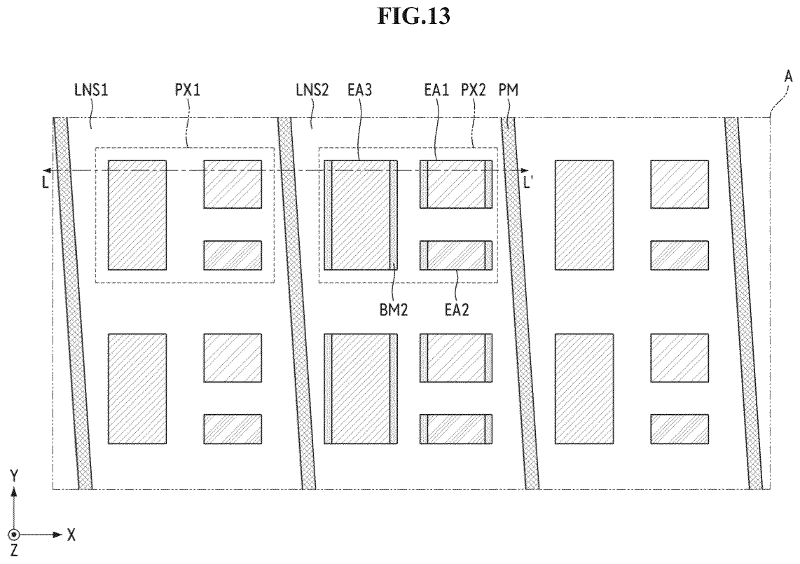

FIG. 13 is an enlarged view of portion A of FIG. 2. The following description will focus on differences and the redundant description may be omitted for economy of explanation.

Referring to FIG. 13, the optical member 200 may comprise a polarizing member PM (e.g., a polarizer) located between the plurality of lenses LNS. In some embodiments, the polarizing member PM may allow light vibrating in the second direction (e.g., the Y-axis direction) to pass through and may block light vibrating in the first direction (e.g., the X-axis direction). By doing so, the polarizing member PM may selectively block light emitted from the light-emitting areas EA1, EA2 and EA3 according to the polarization direction.

Although the plurality of second light-blocking members BM2 is arranged on the first side and the second side of each of the light-emitting areas EA1, EA2 and EA3 of the second group included in the second pixel group PX2 in the example shown in FIG. 13, embodiments of the present disclosure are not necessarily limited thereto. As described above with reference to FIG. 7, the plurality of second light-blocking members BM2 may also be arranged on the first side to the fourth side of each of the light-emitting areas EA1, EA2 and EA3 of the second group.

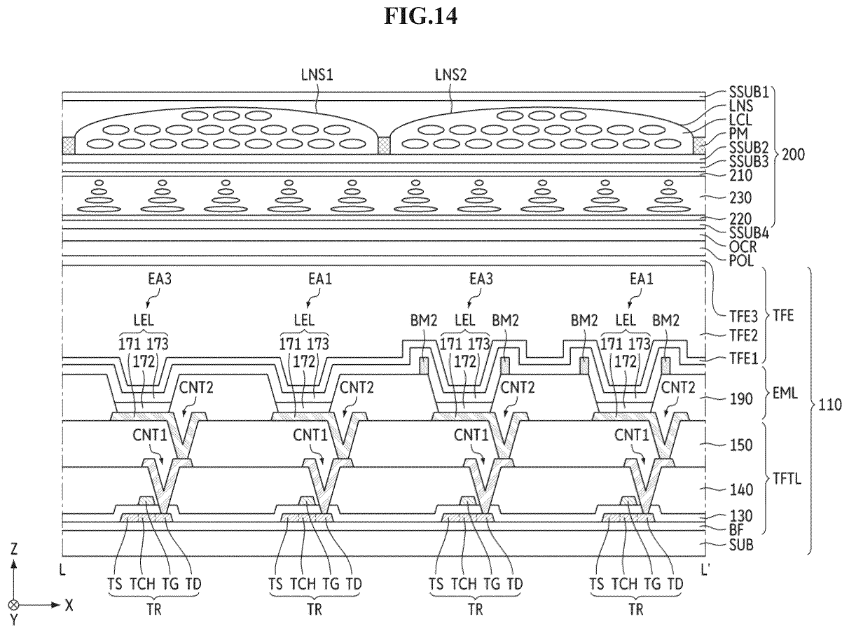

FIG. 14 is a cross-sectional view of the display device, taken along line L-L′ of FIG. 13. The following description will focus on differences and the redundant description may be omitted for economy of explanation.

Referring to FIG. 14, a polarizing member PM may be arranged between a plurality of lenses LNS. In the third direction (e.g., the Z-axis direction), the polarizing member PM may not overlap with a plurality of second light-blocking members BM2.

In some embodiments, the polarizing member PM may allow light vibrating in the second direction (e.g., the Y-axis direction) to pass through. In the 2D mode, the major axis of the driving liquid crystals 230 may be aligned in the first direction (e.g., the X-axis direction) at the lower portion of the driving liquid crystals 230 and may be changed gradually towards the upper portion of the driving liquid crystals 230 and may be aligned in the second direction (e.g., the Y-axis direction) at the upper portion of the driving liquid crystals 230. In the first period, lights emitted from the light-emitting areas EA1, EA2 and EA3 of the first group may be polarized in the first direction (e.g., the X-axis direction) through the polarization layer POL. Subsequently, the light polarized in the first direction (e.g., the X-axis direction) is polarized in the second direction (e.g., the Y-axis direction) through the driving liquid crystals 230 and then passes through the polarizing member PM.

In the 3D mode, the major axis of the driving liquid crystals 230 may be aligned in the third direction (e.g., the Z-axis direction). Accordingly, the lights emitted from the light-emitting areas EA1, EA2 and EA3 of the second group in the second period may be polarized in the first direction (e.g., the X-axis direction) through the polarization layer POL. Subsequently, the lights polarized in the first direction (e.g., the Xx-axis direction) may maintain the polarization direction even through the driving liquid crystals 230. Therefore, the polarizing member PM can block the light emitted by the second group of light-emitting areas EA1, EA2 and EA3 in the 3D mode. In this manner, according to an embodiment, it is possible to prevent 3D crosstalk by blocking the light traveling between the plurality of lenses LNS.

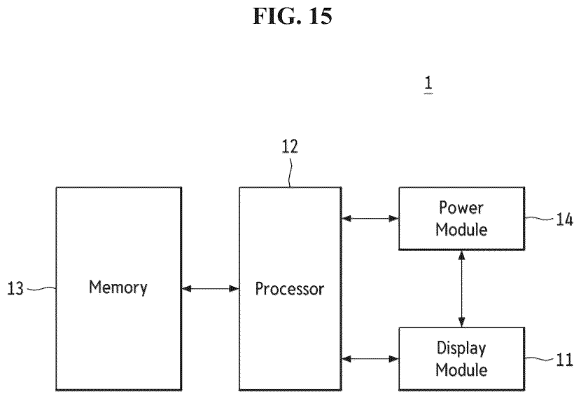

FIG. 15 is a block diagram showing an example of an electronic device including a display device according to some embodiments of the present disclosure.

Referring to FIG. 15, an electronic device 1 according to an embodiment of the present disclosure may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to embodiments described above. In some embodiments, some of the individual modules functioning as a single module may be included in the display device while some others may be provided separately from the display device. In some embodiments, the display device may include the display module 11, and the processor 12, the memory 13 and the power module 14 may be implemented as other devices inside the electronic device 1 instead of the display device.

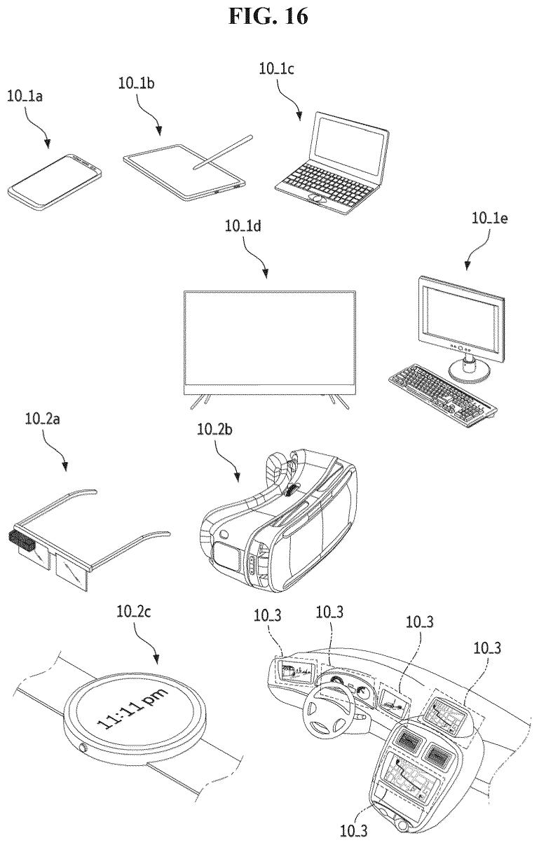

FIG. 16 is a view showing an example of an electronic device including a display device according to some embodiments of the present disclosure.

Referring to FIG. 16, a variety of electronic devices employing display devices according to embodiments may include not only image display electronic devices such as a smart phone 10_1a, a tablet PC 10_1b, a laptop computer 10_1c, a TV 10_1d and a desktop monitor 10_1e, but also wearable electronic devices including display modules such as smart glasses 10_2a, a head-mounted display 10_2b and a smart watch 10_2c, and electronic devices for vehicles 10_3 including display modules such as a center information display (CID) placed on the dashboard, the center fascia and the dashboard of a vehicle, and a room mirror display.

It should be understood, however, that the aspects and features of embodiments of the present disclosure are not restricted to those set forth herein.

What is claimed is:

1. A display device comprising:
a display panel; and
an optical member disposed on the display panel and comprising a plurality of lenses that refracts light output from the display panel, and a plurality of first light-blocking members arranged between the plurality of lenses,
wherein the display panel comprises:
a substrate;
a plurality of pixel electrodes arranged on the substrate;
a pixel-defining layer exposing a portion of each of the plurality of pixel electrodes and defining a plurality of light-emitting areas;
a plurality of light-emitting layers arranged on the plurality of pixel electrodes in the plurality of light-emitting areas;
a common electrode arranged on the plurality of light-emitting layers and the pixel-defining layer; and
a plurality of second light-blocking members arranged on the pixel-defining layer and each arranged on at least one side of the plurality of light-emitting areas, and
wherein a minimum distance between first light-blocking members adjacent to each other in a first direction parallel to an upper surface of the substrate among the plurality of first light-blocking members is a first distance,
a minimum distance between second light-blocking members adjacent to each other in the first direction among the plurality of second light-blocking members is a second distance that is less than the first distance.

2. The display device of claim 1, wherein each of the plurality of second light-blocking members surrounds a light-emitting area of the plurality of light-emitting areas on a plane.

3. The display device of claim 1, wherein:
the plurality of light-emitting areas are arranged adjacent to each other in the first direction and a second direction perpendicular to the first direction on a plane; and
the plurality of lenses extend in a third direction crossing the first direction and the second direction on the plane.

4. The display device of claim 3, wherein the plurality of first light-blocking members extend in the third direction on the plane.

5. The display device of claim 1, wherein a height of the plurality of second light-blocking members is less than a height of the pixel-defining layer in a thickness direction of the substrate.

6. The display device of claim 1, wherein the plurality of second light-blocking members are arranged between the pixel-defining layer and the common electrode.

7. The display device of claim 1, further comprising:
an encapsulation layer disposed on the common electrode,
wherein the plurality of second light-blocking members are arranged between the common electrode and the encapsulation layer.

8. The display device of claim 1, wherein:
each of the plurality of light-emitting areas comprises first to fourth sides,
wherein the first side is adjacent to one of the plurality of second light-blocking members,
the second side is opposite to the first side on a plane,
the third side connects a first end of the first side with a first end of the second side, and
the fourth side connects an opposite second end of the first side with an opposite second end of the second side, and
the plurality of second light-blocking members is solely arranged on the first side and the second side of the plurality of light-emitting areas.

9. The display device of claim 1, wherein the plurality of light-emitting areas comprise:
a first group of light-emitting areas that emit light in a first period; and
a second group of light-emitting areas that emit light in a second period different from the first period.

10. The display device of claim 9, wherein the plurality of second light-blocking members is solely arranged on at least one side of the first group of light-emitting areas.

11. The display device of claim 1, wherein the optical member further comprises a polarizer.

12. The display device of claim 1, wherein the optical member further comprises:
a first base substrate disposed on a first side of the plurality of lenses and a second base substrate disposed on an opposite second side of the plurality of lenses; and
a liquid-crystal layer arranged on the plurality of lenses and the plurality of first light-blocking members and in direct contact with a lower surface of the first base substrate.

13. The display device of claim 1, wherein the optical member further comprises:
a first base substrate disposed on a first side of the plurality of lenses and a second base substrate disposed on an opposite second side of the plurality of lenses; and
a polarization controller disposed on a lower surface of the second base substrate that outputs light incident from the display panel as one of a first polarized light and a second polarized light.

14. The display device of claim 13, wherein the polarization controller comprises:
a third base substrate in direct contact with the lower surface of the second base substrate;
a fourth base substrate facing the third base substrate;
a first driving electrode disposed on a surface of the third base substrate;
a second driving electrode disposed on a surface of the fourth base substrate and facing the first driving electrode; and
a driving liquid crystal disposed between the first driving electrode and the second driving electrode.

15. The display device of claim 14, wherein in response to a voltage difference between the first driving electrode and the second driving electrode that is less than or equal to a first value, a major axis of the driving liquid crystal is aligned in the first direction at a lower portion of the driving liquid crystal, is changed gradually towards an upper portion of the driving liquid crystal and is aligned in a second direction perpendicular to the first direction at the upper portion of the driving liquid crystal.

16. The display device of claim 15, wherein in response to the voltage difference between the first driving electrode and the second driving electrode that is greater than the first value, the major axis of the driving liquid crystal is aligned in a third direction perpendicular to the first direction and the second direction.

17. An electronic device comprising:
a display device having a display panel and an optical member disposed on the display panel,
wherein the optical member comprises:
a plurality of lenses that refracts light output from the display panel; and
a plurality of first light-blocking members arranged between the plurality of lenses,
wherein the display panel comprises:
a substrate;
a plurality of pixel electrodes arranged on the substrate;
a pixel-defining layer exposing a portion of each of the plurality of pixel electrodes and defining a plurality of light-emitting areas;
a plurality of light-emitting layers arranged on the plurality of pixel electrodes in the plurality of light-emitting areas;
a common electrode arranged on the plurality of light-emitting layers and the pixel-defining layer; and
a plurality of second light-blocking members arranged on the pixel-defining layer and each arranged on at least one side of the plurality of light-emitting areas, and
wherein a minimum distance between first light-blocking members adjacent to each other in a first direction parallel to an upper surface of the substrate among the plurality of first light-blocking members is a first distance,
a minimum distance between second light-blocking members adjacent to each other in the first direction among the plurality of second light-blocking members is a second distance less than the first distance.

18. The electronic device of claim 17, wherein each of the plurality of second light-blocking members surrounds a light-emitting area of the plurality of light-emitting areas on a plane.

19. The electronic device of claim 17, wherein:
each of the plurality of light-emitting areas comprises first to fourth sides,
wherein the first side is adjacent to one of the plurality of second light-blocking members,
the second side is opposite to the first side on a plane,
the third side connects a first end of the first side with a first end of the second side, and
the fourth side connects an opposite second end of the first side with an opposite second end of the second side, and
the plurality of second light-blocking members is solely arranged on the first side and the second side of the plurality of light-emitting areas.

20. The electronic device of claim 17, wherein the plurality of light-emitting areas comprise:
a first group of light-emitting areas that emit light in a first period; and
a second group of light-emitting areas that emit light in a second period different from the first period.
